(19) United States
(12) Patent Application Publication
(10) Pub. No.: US 2011/0278048 A1
(43) Pub. Date: Nov. 17, 2011

(54) STRUCTURE FOR CONNECTING FLEXIBLE CIRCUIT TO TARGET MEMBER

(76) Inventor: Kenshi Numakura, Haverhill, MA (US)

(21) Appl. No.: 13/146,358

(22) PCT Filed: Jan. 27, 2009
(86) PCT No.: PCT/JP2009/051258

§ 371 Date: Jul. 26, 2011

(51) Int. Cl. H05K 1/00

(52) U.S. Cl. 174/254

(57) ABSTRACT

A high-density, narrow-pitch, and high-pin-count connecting structure with a very low mounting height is realized at low cost.

A flexible circuit 10 has first through holes 15 in a plane of first contact pads 13, the first through holes 15 passing through the flexible circuit 10 in a thickness direction of the flexible circuit 10. A target member 20 has second holes 25 in a plane of second contact pads 23, the second holes 25 passing through the target member 20 in a thickness direction of the target member 20. A connector main body 30 has first protrusions 33 on one surface of a third base 31, the first protrusions 33 corresponding to the first through holes 15 of the flexible circuit 10 and the second holes 25 of the target member 20. The connector main body 30 is pressed against the flexible circuit 10 disposed such that the first contact pads 13 face the second contact pads 23, so that the first protrusions 33 are passed through the first through holes 15 and inserted into the second holes 25, the flexible circuit 10 is mechanically connected to the target member 20, and an electrical connection between the first contact pads 15 and the second contact pads 15 is established by pressure contacting.

### TECHNICAL FIELD

The present invention relates to a connecting structure for connecting a flexible circuit to a target member. In particular, the present invention relates to a connecting structure for detachably connecting a flexible circuit including a plurality of conductor circuits to a target member, such as a circuit component or a printed circuit board including a plurality of conductor circuits.

### BACKGROUND ART

As electronic devices have become smaller and lighter in recent years, thin and bendable printed circuit boards, or in particular, thin plastic-film-based flexible printed circuit boards (FPCs) have become more frequently used in designing such electronic devices. As connecting means of repeatedly attaching and detaching such a thin flexible circuit to and from another printed circuit board (PCB or PWB) or a circuit component, various connecting techniques and connectors have been used.

One is called an FFC connector developed for connection of flexible flat cables (FFCs). The FFC connector is mounted by soldering onto a printed circuit board. Then terminals of a thin flexible circuit are inserted into the FFC connector to establish an electrical connection. FFC connectors with lower mounting heights and smaller connection pitches are being developed every year. In the latest design, a product with a height of 0.8 mm and a connection pitch of 0.3 mm is in practical use.

Another is called a board-to-board connector (BTB connector). The BTB connector is composed of a set of male and female connectors, one being mounted by soldering onto a flexible circuit and the other being mounted by soldering onto a target printed circuit board. The male and female connectors are mated together to establish an electrical connection. BTB connectors are higher in connection height and more expensive than FFC connectors. However, because of their higher reliability, BTB connectors are often used in mobile phones and digital cameras. BTB connectors with lower mounting heights and smaller connection pitches are being developed every year. In the latest design, a product with a height of 1.1 mm and a connection pitch of 0.4 mm is in practical use.

Development of smaller-size narrower-pitch FFC and BTB connectors is under study. However, considering the workability of contact terminals and housing and the manufacturability of connectors, FFC connectors with a height of about 0.5 mm and a connection pitch of about 0.25 mm are seen as limits, and BTB connectors with a height of about 0.6 mm and a connection pitch of about 0.3 mm are seen as limits. According to basic structures of these connectors, the manufacturing cost per pin increases exponentially as size reduction proceeds. In particular, as the number of pins in BTB connectors increases, the cost involved in manufacturing the final electronic devices increases significantly.

Another technique is called a dimple flex connection. In this technique, protrusions are formed by dimpling in which contact pad portions of a flexible circuit are pressed from under a base film. The protrusions are pressed against a flat target printed circuit board to establish an electrical connection. To ensure the connection, a pressure is applied to the backside of the flexible circuit with a rubber mold. This connecting structure makes it possible to realize a high-pin-count connection at low cost, and thus is often used, for example, in ink cartridges of inkjet printers. In the latest design, a connection with a pitch of about 1.0 mm is in practical use.

The dimple flex connection involves a special process of dimpling a flexible circuit. This causes a significant manufacturing burden and leads to problems in applicability. Additionally, since dimple terminals are point contacts, it is difficult to allow a large current to flow through the dimple terminals. Considering the workability, a pitch of about 0.8 mm is seen as a limit. To realize uniform terminal contact in a high-pin-count structure, it is necessary to increase the size of the rubber mold and the thickness of a base that supports the rubber mold. Therefore, the dimple flex connection is practically not suitable for use in a thin connecting structure.

As a low-mounting-height connecting structure for flexible circuits, a connecting structure using a film connector with a bump array has been proposed recently (see, e.g., Non-Patent Document 1). This connecting structure includes a film connector obtained by forming a micro-bump array on a thin heat-resistant film, and a flexible circuit having a female structure corresponding to the film connector. The film connector is mounted to another printed circuit board by soldering. An electrical connection is established by pressing the flexible circuit against the film connector, the flexible circuit having holes aligned with the bump array of the film connector.

However, in the structure where an electrical connection between the flexible circuit and the target printed circuit board is made through the micro-bumps of the film connector, it is costly and very difficult to accurately form the specially-structured micro-bumps that pass through a film.

Additionally, with the simple structure in which the holes of the flexible circuit are pressed against the micro-bumps, a force that holds the flexible circuit is small and it is difficult to realize a shock-resistant reliable holding force.

As for mounting of the film connector onto the printed circuit board, unlike in the cases of mounting of a rigid printed circuit board, an IC chip, and other components, it is difficult to realize a BGA structure by attaching solder balls or the like to the backside of the film connector which is flexible. Therefore, the film connector described above is practically unusable as an inexpensive connector for consumer portable electronic devices, such as mobile phones, portable digital audio players, and portable game machines.

As a low-mounting-height connecting structure for flexible circuits, a connecting structure has been proposed in which tapered conductive protrusions on a film circuit board are inserted into through holes of a circuit board (e.g., a rigid printed wiring board or a ceramic substrate) having pads (see, e.g., FIG. 42 in Patent Document 1).

The connecting structure described above is a very special structure in which three-dimensional conductive protrusions electrically connected to conductor circuits included in the film circuit board are formed on the film circuit board. Therefore, the connecting structure requires a special manufacturing process, causes a large manufacturing burden, and increases the price of the final product. Additionally, a wiring structure for electrically connecting the conductor circuits and the conductive protrusions needs to be carefully considered in designing such a special film circuit board. This presents a significant problem in application to narrow-pitch high-pin-count structures.

As another structure for electrically connecting a flexible circuit to a printed circuit board, a connecting structure has been proposed in which an electrical connection is established by placing a flexible circuit on a printed circuit board, and press-fitting a conductive contact piece having a diameter larger than that of a through hole of the printed circuit board into the through hole of the printed circuit board such that the contact piece passes through a wiring portion of the flexible circuit (see, e.g., Patent Document 2). As still another structure for electrically connecting a flexible circuit to a printed circuit board, a connecting structure has been proposed in which a pressure contacting member, which is a thin plate-like spring member, is used to pressure-contact a conductor surface of a connecting portion of a flexible circuit to a conductor surface of a connecting portion of a printed circuit board and establish an electrical connection therebetween (see, e.g., Patent Document 3).

Patent Document 2 specifically concerns a technique of electrically connecting flexible circuit to a printed circuit board without removing a coating at an end portion of the flexible circuit and without using a connector. The connecting structure disclosed in Patent Document 2 does not effectively function unless a good reliable contact state is ensured between a conductor portion of the flexible circuit and the contact piece that passes therethrough. To meet this requirement, the flexible circuit needs to be one that is made to specific design specifications. Also, if the connecting structure of Patent Document 2 is applied to a high-pin-count structure, the contact state between the conductor portion of the flexible circuit and the contact piece that passes therethrough may be different from one conductor portion to another. Consequently, as the number of pins increases, the reliability decreases at a geometric rate. Therefore, the connecting structure of Patent Document 2 is not suitable for use as a detachable, narrow-pitch, and high-pin-count connecting structure.

The connecting structure disclosed in Patent Document 3 uses a relatively small pressure contacting force of the pressure contacting member, which is a spring member. The small pressure contacting force acts with respect to a supporting portion joined to the printed circuit board. With this structure, the flexible circuits can be relatively easily attached to and detached from the printed circuit board. However, a contact holding force for retaining contact between the conductor portion of the flexible circuits and the conductor portion of the printed circuit board is small. Therefore, it is difficult to realize a shock-resistant reliable holding force.
Non-Patent Document 1: “Film Connectors for Ultra Thin Connections In High Density Flexible Circuits” News Release from DKN Research, Haverhill Mass., et al., July 2007 (http://www.dknresearch.com/0707NewsFilmConEng.pdf)
Patent Document 1: International Publication No. WO 2008/050448
Patent Document 2: Japanese Unexamined Patent Application Publication No. 2001-332853
Patent Document 3: Japanese Unexamined Patent Application Publication No. 2008-98260

### DISCLOSURE OF INVENTION

### Problems to be Solved by the Invention

As described above, in the connecting structures of related art, (i) it is difficult to physically realize a thin, high-density, narrow-pitch, and high-pin-count connecting structure; (ii) a special film connector with specially-structured micro-bumps that pass through a film, and a specially-structured film circuit board having three-dimensional conductive protrusions are hard to manufacture and costly; (iii) it is difficult to ensure a reliable contact state between a conductor portion of a flexible circuit and a contact piece that passes therethrough in detachable, narrow-pitch, and high-pin-count design; and (iv) a force that holds a flexible circuit is small, and it is difficult to realize a shock-resistant reliable holding force.

The present invention has been made in view of the problems described above. An object of the present invention is to provide a connecting structure for connecting a flexible circuit to a target member, the connecting structure being a structure that realizes a high-density, narrow-pitch, and high-pin-count connecting structure with a very low mounting height at low cost.

Another object of the present invention is to provide a connecting structure for connecting a flexible circuit to a target member, the connecting structure being a structure that realizes a connecting structure having a shock-resistant reliable holding force at low cost.

### Means for Solving the Problems

To achieve the objects described above, a connecting structure for connecting a flexible circuit to a target member according to the present invention includes a flexible circuit having first contact pads on at least one surface thereof, the first contact pads being connected to respective first conductor circuits; a target member having second contact pads on at least one surface thereof, the second contact pads being connected to respective second conductor circuits; and a connector main body configured to detachably connect the a flexible circuit to the target member. The flexible circuit has first through holes in a plane of the first contact pads, the first through holes passing through the flexible circuit in a thickness direction of the flexible circuit; the target member has second holes in a plane of the second contact pads, the second holes being formed in a depth direction of the target member and deeper than a thickness of the second contact pads; and the connector main body has first protrusions on one surface of a third base, the first protrusions corresponding to the first through holes of the flexible circuit and the second holes of the target member. The connector main body is pressed against the flexible circuit disposed such that the first contact pads face the corresponding second contact pads of the target member, so that the first protrusions of the connector main body are passed through the first through holes of the flexible circuit and inserted into the second holes of the target member, the flexible circuit is mechanically connected to the target member, and an electrical connection between the first contact pads and the second contact pads is established by pressure contacting.

In a preferred embodiment of the present invention, the second holes of the target member are double-sided through holes or blind holes, each having a conductor layer on an inner surface thereof.

In the present invention, preferably, the first contact pads are contact pads arranged in an array on the one surface of the flexible circuit, the second contact pads are contact pads arranged in an array on the one surface of the target member, and the first protrusions are protrusions arranged in an array on the one surface of the third base of the connector main body, the first protrusions corresponding to the first through holes of the first contact pads and the second holes of the second contact pads.

In a preferred embodiment of the present invention, the connector main body may include a reinforcing member on the other surface of the third base, the reinforcing member being configured to apply an external force to the first protrusions arranged in an array.

In a preferred embodiment of the present invention, the flexible circuit further has third through holes for positioning, the third through holes being at a distance from the first conductor circuits and the first contact pads; the target member further has fourth holes for positioning, the fourth holes being at a distance from the second conductor circuits and the second contact pads; and the connector main body has second protrusions for positioning on the one surface of the third base, the second protrusions corresponding to the third through holes and the fourth holes.

In a preferred embodiment of the present invention, the flexible circuit has the first through holes smaller in size than the second holes of the target member and the first protrusions of the connector main body, the second holes and the first protrusions being substantially the same in size; and when the first protrusions are passed through the first through holes and inserted into the second holes, the first protrusions press the corresponding inner edges of the first contact pads into the second holes to establish a frictional connection between the flexible circuit and the target member.

In a preferred embodiment of the present invention, the first protrusions have a shape of a truncated cone, and a diameter of an upper base of each of the first protrusions being truncated cones is greater than or equal to a quarter of a height of the truncated cone.

In a preferred embodiment of the present invention, the connecting structure further includes a securing member adjacent to the reinforcing member of the connector main body, the securing member being configured to secure the third base to the target member.

In a preferred embodiment of the present invention, the securing member and the reinforcing member of the connector main body may be disposed such that one end face of the securing member and one end face of the reinforcing member are adjacent to each other at a predetermined distance, and the securing member and the reinforcing member may form a hinge mechanism which allows the connector main body to pivot about a portion of the third base that bridges a gap between the securing member and the reinforcing member.

The securing member may have third protrusions engaged in the target member.

### Advantages

According to the present invention, a high-density, narrow-pitch, and high-pin-count connecting structure with a very low mounting height can be realized at low cost. At the same time, a connecting structure having a shock-resistant reliable holding force can be realized at low cost.

The foregoing and other objects and advantages of the present invention can be more clearly understood through the description of the following embodiments. Note that the embodiments described below are merely examples, and the present invention is not limited to them.

### BRIEF DESCRIPTION OF DRAWINGS

FIG. 1A is an enlarged cross-sectional view illustrating a main part of a connecting structure before assembly according to an embodiment of the present invention.

FIG. 1B is an enlarged cross-sectional view illustrating the main part of FIG. 1A after assembly.

FIG. 2A is an enlarged cross-sectional view illustrating a main part of a connecting structure before assembly according to another embodiment of the present invention.

FIG. 2B is an enlarged cross-sectional view illustrating the main part of FIG. 2A after assembly.

FIG. 3A is an enlarged cross-sectional view illustrating a main part of a connecting structure before assembly according to another embodiment of the present invention.

FIG. 3B is an enlarged cross-sectional view illustrating the main part of FIG. 3A after assembly.

FIG. 4 is an enlarged cross-sectional view illustrating a main part of a connecting structure according to another embodiment of the present invention.

FIG. 5 is an enlarged cross-sectional view illustrating a main part of a connecting structure according to another embodiment of the present invention.

FIG. 6 is an enlarged cross-sectional view illustrating a main part of a connecting structure according to another embodiment of the present invention.

FIG. 7 is a plan view illustrating a connector in a connecting structure according to another embodiment of the present invention.

FIG. 8A is a cross-sectional view taken along line A-A′ of FIG. 7.

FIG. 8B is a cross-sectional view taken along line B-B′ of FIG. 7.

FIG. 9A is a cross-sectional view illustrating the connecting structure of FIG. 7 before assembly.

FIG. 9B is a cross-sectional view illustrating the connecting structure of FIG. 7 after assembly.

FIG. 10 is a plan view illustrating a connector in a connecting structure according to another embodiment of the present invention.

FIG. 11A is a cross-sectional view taken along line C-C′ of FIG. 10.

FIG. 11B is a cross-sectional view taken along line D-D′ of FIG. 10.

FIG. 12A is a cross-sectional view illustrating the connecting structure of FIG. 10 before assembly.

FIG. 12B is a cross-sectional view illustrating the connecting structure of FIG. 10 after assembly.

FIG. 13 is a cross-sectional view illustrating a connecting structure according to another embodiment of the present invention.

### REFERENCE NUMERALS

10 flexible circuit
13 first contact pad
15 first through hole
20 target member
23 second contact pad
25 second hole
30 connector main body
31 third base
33 first protrusion

### BEST MODES FOR CARRYING OUT THE INVENTION

Preferred embodiments of the present invention will now be described in detail with reference to the drawings.

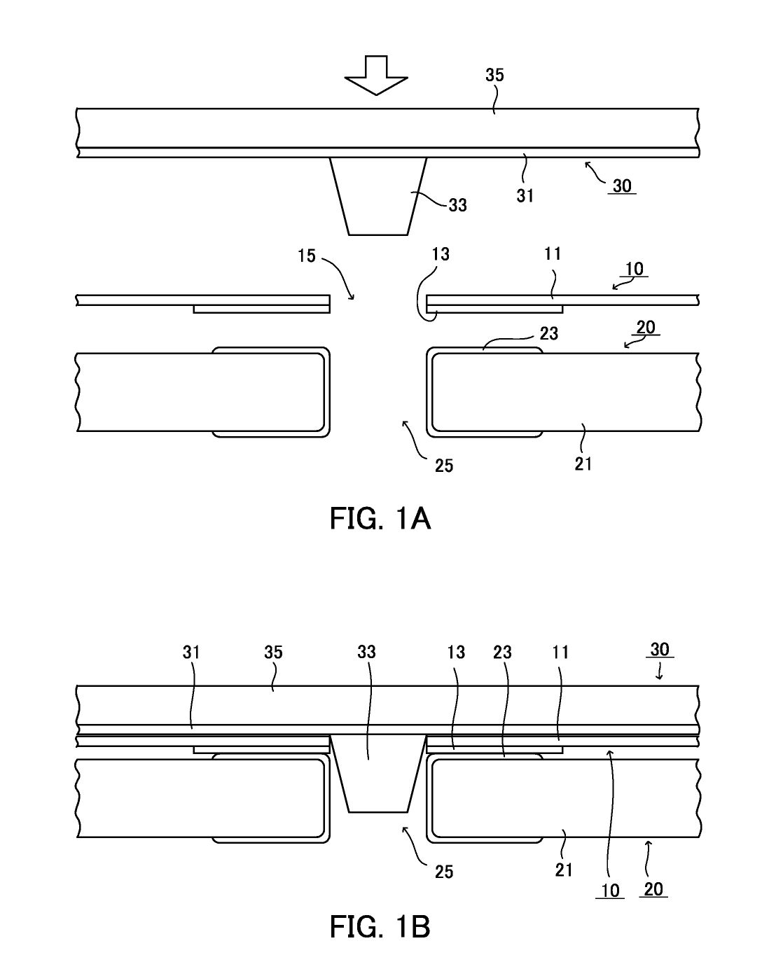

FIG. 1A and FIG. 1B are enlarged cross-sectional views illustrating a main part of a connecting structure before and after assembly according to an embodiment of the present invention.

The connecting structure of the embodiment illustrated in FIG. 1A and FIG. 1B includes a flexible circuit 10 having a first contact pad 13 on one surface thereof, the first contact pad 13 being connected to one of a plurality of first conductor circuits (not shown) included in a first base 11; a target member 20 having a second contact pad 23 on one surface thereof, the second contact pad 23 being connected to one of a plurality of second conductor circuits (not shown) included in a second base 21; and a connector main body 30 configured to detachably connect the flexible circuit 10 to the target member 20.

The flexible circuit 10 has a first through hole 15 in a plane of the first contact pad 13, the first through hole 15 passing through the flexible circuit 10 in a thickness direction of the flexible circuit 10. The target member 20 has a second hole 25 in a plane of the second contact pad 23, the second hole 25 passing through the target member 20 in a thickness direction of the target member 20. The connector main body 30 has a first protrusion 33 on one surface of a third base 31, the first protrusion 33 corresponding to the first through hole 15 of the flexible circuit 10 and the second hole 25 of the target member 20.

As a base of the first base 11 of the flexible circuit 10, a dielectric film made of polyethylene resin or heat-resistant resin, such as polyimide (PI) resin, polyethylene naphthalate (PEN) resin, epoxy resin, liquid crystal polymer resin, polyether etherketone (PEEK) resin, or polyethylene terephthalate (PET) resin, can be used. The plurality of first conductor circuits (not shown) are formed by etching a copper-clad laminate of copper foil on the dielectric film, or by printing a conductive paste or ink on the dielectric film. The plurality of first conductor circuits are covered with a cover lay as necessary. The first contact pad 13 and the first through hole 15 in the plane of the first contact pad 13, the first through hole 15 passing through the flexible circuit 10 in the thickness direction of the flexible circuit 10, can be formed by a typical etching technique and a typical through-hole processing technique.

For example, if a rigid printed circuit board is used as the target member 20, a rigid glass epoxy member can be used as a base of the second base 21 of the target member 20. The plurality of second conductor circuits (not shown) are formed by etching a copper-clad laminate of copper foil on the glass epoxy member, or by printing a conductive paste or ink on the glass epoxy member. The second contact pad 23 and the second hole 25 in the plane of the second contact pad 23, the second hole 25 passing through the target member 20 in the thickness direction of the target member 20, can be formed by a combination of a typical etching technique and a typical through-hole processing technique (e.g., mechanical drilling or laser cutting). In the present embodiment, the second hole 25 is a double-sided through hole formed by plating the inner periphery with conductive material. Such a through-hole forming method is a known technique used in manufacture of printed circuit boards, and thus will not be described in detail.

The target member 20 is not limited to a typical rigid printed circuit board, but may be a ceramic substrate, a circuit component (e.g., IC chip or LSI chip), a multilayer rigid flex circuit board, or a relatively thick flexible circuit.

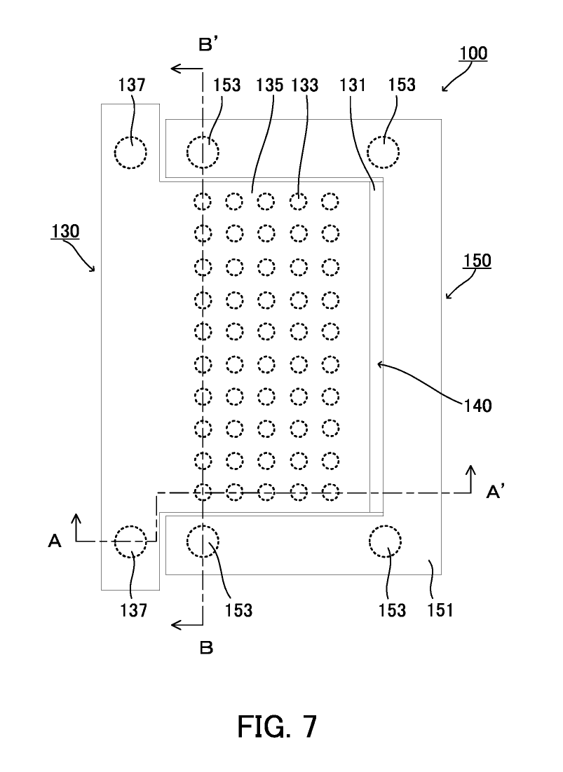

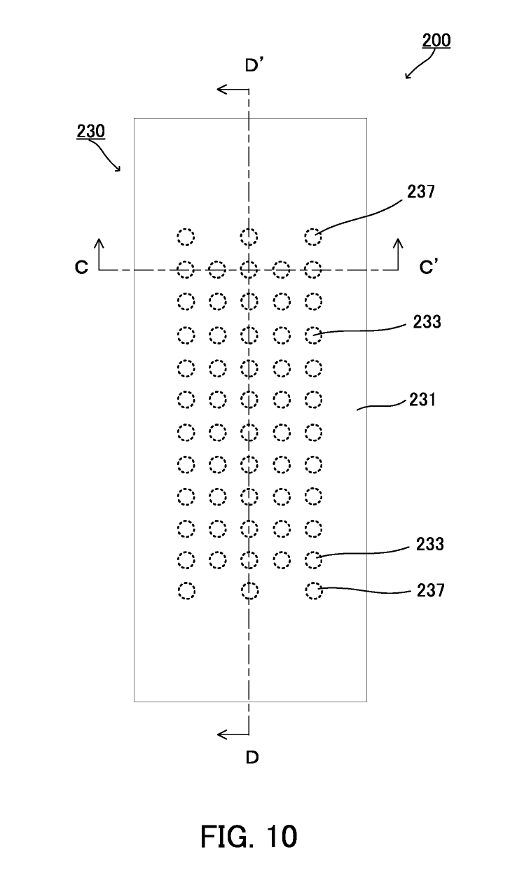

The connector main body 30 has a plurality of first protrusions 33 on one surface of the third base 31. The third base 31 is a thin film-like member serving as a base of the connector main body 30. As described below, in the connecting structure suitable as a high-density, narrow-pitch, and high-pin-count connecting structure, when the first contact pads 13 are arranged in an array on one surface of the flexible circuit 10 and the second contact pads 23 are arranged in an array on one surface of the target member 20, the first protrusions 33 are arranged in an array on one surface of the third base 31 at positions corresponding to the first through holes 15 of the first contact pads 13 and the second holes 25 of the second contact pads 23 (see, e.g., FIG. 7 and FIG. 10). A reinforcing member 35 for applying an external force to the first protrusions 33 arranged in an array is disposed on the other surface of the third base 31 of the connector main body 30.

As a base of the thin film-like third base 31, a dielectric film made of polyethylene resin or heat-resistant resin, such as polyimide (PI) resin, polyethylene naphthalate (PEN) resin, epoxy resin, liquid crystal polymer resin, polyether etherketone (PEEK) resin, or polyethylene terephthalate (PET) resin, can be used. The shape of the first protrusions 33 is not limited to a specific one, but is preferably a circular cylindrical shape or more preferably a truncated cone shape such as that illustrated in the drawings. In the present embodiment, the diameter (size) of the first through holes 15 of the flexible circuit 10, the diameter (size) of the second holes 25 of the target member 20, and the diameter (size) of a lower base of each of the first protrusions 33 (truncated cones) of the connector main body 30 are substantially the same. In this case, if the first protrusions 33 are configured such that the diameter of an upper base of each of the first protrusions 33 (truncated cones) is greater than or equal to a quarter of a height of the truncated cone, it is possible to ensure a minimum level of desired holding force that holds the flexible circuit 10.

If the first protrusions 33 are assumed to be produced by chemical etching, the material of the first protrusions 33 can be stainless steel, copper, nickel, phosphor bronze, brass, another metal, or electroplated or electroless-plated metal. In the present invention, it should be noted that the first protrusions do not require conductivity. Therefore, other than metal, rigid plastic or the like can be used as a material of the first protrusions 33. The same material as that of the first protrusions 33 can be used as a material of the reinforcing member 35. If the first protrusions 33 and the reinforcing member 35, which are main parts of the connector main body 30, are made of plastic, it is possible to use processing such as injection molding. This can significantly reduce the cost of manufacturing the connector main body 30.

As described above, the connector main body 30 has a simple structure in which the first protrusions 33 are on one surface of the thin film-like third base 31 and the reinforcing member 35 is on the other surface of the third base 31. Therefore, by photolithography and etching (and electroforming, which may be added as necessary) or by processing such as injection molding, the connector main body 30 can be produced in quantity while the positional relationships of the first protrusions 33 are being very accurately controlled. Specifically, with the current technology, a connector main body having the first protrusions 33 arranged in a high-density, narrow-pitch, and high-pin-count array with a pitch of less than 0.2 mm can be produced in quantity with an accuracy of within ±0.020 mm. Such a connector main body allows connection of a high-density flexible circuit including conductor circuits with a pitch of less than 0.050 mm. Unlike connectors of related art, such a connector main body does not require assembly of a housing and terminals. It is thus possible to realize a high-density, narrow-pitch, and high-pin-count structure with a very low mounting height, and to significantly reduce costs as compared to connectors of related art.

The flexible circuit 10, the target member 20, and the connector main body 30 configured as described above are positioned as illustrated in FIG. 1A. Then, an external force is perpendicularly applied from above to the reinforcing member 35 of the connector main body 30 to obtain the connecting structure illustrated in FIG. 1B. Specifically, the connector main body 30 is pressed against the flexible circuit 10 disposed such that the first contact pad 13 faces the corresponding second contact pad 23 of the target member 20, so that the first protrusion 33 of the connector main body 30 is passed through the first through hole 15 of the flexible circuit 10 and inserted into the second hole 25 of the target member 20, the flexible circuit 10 is mechanically connected to the target member 20, and an electrical connection between the first contact pad 13 and the second contact pad 23 is established by pressure contacting.

The connection between the flexible circuit 10 and the target member 20 can be released by raising the connector main body 30 to pull the first protrusion 33 out of the first through hole 15 and the second hole 25.

An advantage of the detachable connecting structure of the present embodiment is that the electrical connection described above is very reliable. This is because the contact pads are brought into contact with each other in a ring shape by pressure contacting and, in addition, are subjected to pressure from the first protrusion 33 (in particular, a portion near the lower base of the truncated cone) above them. Moreover, since the reinforcing member in the upper part of the connector main body 30 causes the first protrusion 33 to effectively exert an external force (pressing force), reliability of the mechanical connection is improved. At the same time, a height above the front surface of the target member 20 is equal to a sum of the thickness of the flexible circuit 10 including the first contact pad 13 and the thickness of the connector main body 30 including the third base 31 and the reinforcing member 35. Thus, a connecting structure with a very low mounting height can be realized.

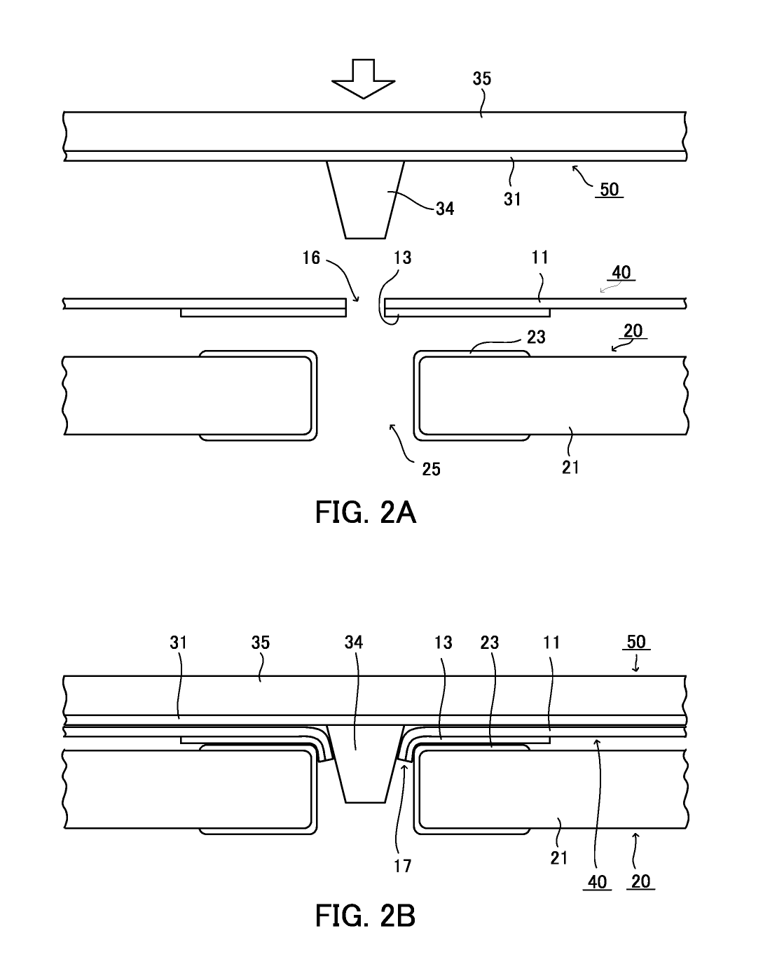

FIG. 2A and FIG. 2B are enlarged cross-sectional views illustrating a main part of a connecting structure before and after assembly according to another embodiment of the present invention. In these drawings, the same components as those illustrated in FIG. 1A and FIG. 1B are denoted by the same reference numerals.

The connecting structure of the present embodiment is different from that of the embodiment illustrated in FIG. 1A and FIG. 1B in that a flexible circuit 20 has a first through hole 16 smaller in diameter (size) than the second hole 25 of the target member 20 and a lower base of a first protrusion 34 of the connector main body 50, and that an upper base of the connector main body 50 is substantially equal in diameter (size) to the first through hole 16. The second hole 25 and the lower base of the first protrusion 34 are substantially equal in diameter (size). Again, to ensure a minimum level of desired holding force, it is preferable that the diameter of the upper base of the first protrusion 34 (truncated cone) be greater than or equal to a quarter of a height of the truncated cone.

The flexible circuit 40, the target member 20, and the connector main body 50 configured as described above are positioned as illustrated in FIG. 2A. Then, an external force is perpendicularly applied from above to the reinforcing member 35 of the connector main body 50 to obtain the connecting structure illustrated in FIG. 2B. Specifically, when the first protrusion 34 is passed through the small first through hole 16 and inserted into the second hole 25, the first protrusion 34 presses the inner edge of the first contact pad 13 into the second hole 25 (as indicated by reference numeral 17) to establish a frictional connection between the flexible circuit 40 and the target member 20.

An advantage of the detachable connecting structure of the present embodiment is that because of the larger pressure contacting force, the ring-shaped contact characteristic between the contact pads 13 and 23 is further improved, the reliability of the electrical connection is further improved, and the connector main body 50 is given a self-holding capability based on the frictional connection. Like the embodiment illustrated in FIG. 1A and FIG. 1B, the present embodiment can realize a connecting structure with a very low mounting height.

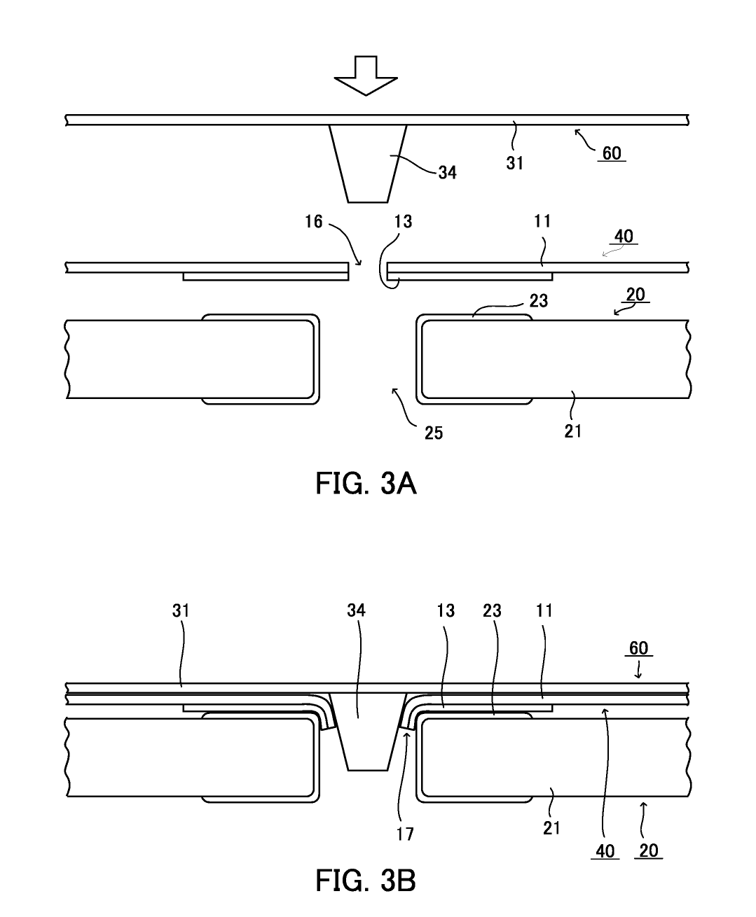

FIG. 3A and FIG. 3B are enlarged cross-sectional views illustrating a main part of a connecting structure before and after assembly according to still another embodiment of the present invention. In these drawings, the same components as those illustrated in FIG. 2A and FIG. 2B are denoted by the same reference numerals.

The connecting structure of the present embodiment is different from that of the embodiment illustrated in FIG. 2A and FIG. 2B in that although a connector main body 60 has the third base 31 and the first protrusion 34, there is no reinforcing member on the other surface of the third base 31. As described above, when the first protrusion 34 is passed through the small first through hole 16 and inserted into the second hole 25, the first protrusion 34 presses the inner edge of the first contact pad 13 into the second hole 25 (as indicated by reference numeral 17) to establish a frictional connection between the flexible circuit 40 and the target member 20. Since this gives the connector main body 60 a self-holding capability based on the frictional connection, it is not necessary to provide a reinforcing member on the other surface of the third base 31. However, for efficient insertion of the first protrusion 34 of the connector main body 60 with a constant force, it is preferable to use, in assembly, an appropriate pressure contacting tool for holding the target member 20 and the connector main body 60 together from both sides.

In the connecting structure of the present embodiment, the connector main body 60 can be made substantially as thin as the third base 31. This is advantageous in that a connecting structure with a lower mounting height can be realized. The other advantages are the same as those of the embodiment illustrated in FIG. 2A and FIG. 2B.

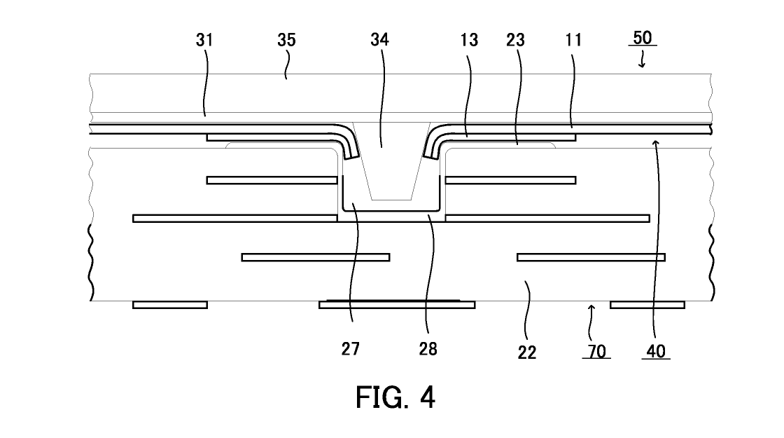

FIG. 4 is an enlarged cross-sectional view illustrating a main part of a connecting structure according to another embodiment of the present invention. In this drawing, the same components as those illustrated in FIG. 2B are denoted by the same reference numerals.

The connecting structure of the present embodiment is different from that of the embodiment illustrated in FIG. 2A and FIG. 2B in that a target member 70 is a multilayer board having a blind via hole. Specifically, the target member 70 is a multilayer board in which a second base 22 includes multiple layers of conductor circuits. The target member 70 has a second hole 27 which is a blind via hole. The second hole 27 is in a plane of the second contact pad 23, extends in a depth direction of the target member 70, and is deeper than the thickness of the second contact pad 23. The inner periphery and the bottom of the second hole 27 are plated with conductive material to form a conductor layer having a predetermined thickness.

The present embodiment has the same advantages as those of the embodiment illustrated in FIG. 2A and FIG. 2B.

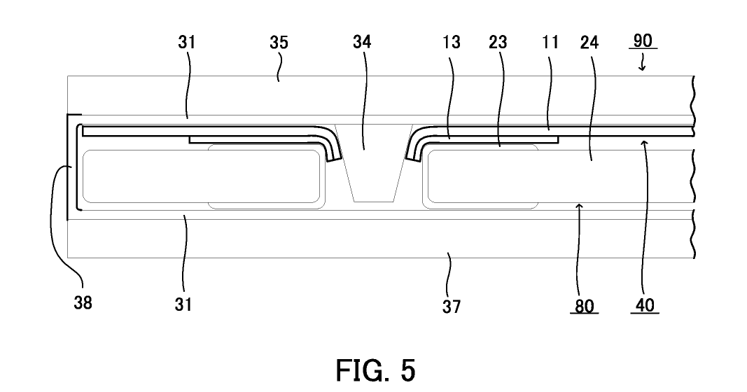

FIG. 5 is an enlarged cross-sectional view illustrating a main part of a connecting structure according to still another embodiment of the present invention. In this drawing, the same components as those illustrated in FIG. 2B are denoted by the same reference numerals.

The connecting structure of the present embodiment is different from that of the embodiment illustrated in FIG. 2A and FIG. 2B in that a target member 80 is composed of a second base 24 which is relatively thin, and that the connecting structure is a sandwich structure which further includes a securing member 37 adjacent to the reinforcing member 35 of a connector main body 90. The securing member 37 is configured to secure the third base 31 to the other surface (backside) of the target member 80. In the present embodiment, the securing member 37 and the reinforcing member 35 are disposed such that one end face of the securing member 37 and one end face of the reinforcing member 35 are adjacent to each other at a predetermined distance. The gap between the securing member 37 and the reinforcing member 35 is bridged by a portion 38 of the third base, so that the securing member 37 and the reinforcing member 35 form a hinge mechanism which allows the connector main body 90 to pivot about the portion 38.

Application of the hinge mechanism allows the connector main body to serve as an opening/closing mechanism, eases the mounting onto the target member 80, and also eases the insertion and securing of the flexible circuit 40. The other advantages are the same as those of the embodiment illustrated in FIG. 2A and FIG. 2B.

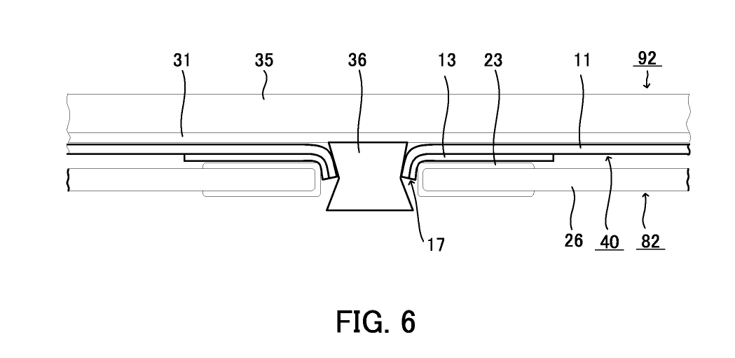

FIG. 6 is an enlarged cross-sectional view illustrating a main part of a connecting structure according to still another embodiment of the present invention. In this drawing, the same components as those illustrated in FIG. 2B are denoted by the same reference numerals.

The connecting structure of the present embodiment is different from that of the embodiment illustrated in FIG. 2A and FIG. 2B in that a target member 82 is composed of a second base 26 which is very thin, and that a connector main body 92 has a first protrusion 36 in the shape of a circular cylinder constricted in the middle in the longitudinal direction.

In the connecting structure of the present embodiment, even if the target member 82 is a very thin member, such as a flexible circuit, it is possible to effectively prevent the target member 82 from falling by allowing a second hole of the target member 82 to be held at the constricted portion of the first protrusion 36.

The main parts of the embodiments of the present invention have been described with reference to the drawings. The present inventor actually made samples and was able to realize high-density, narrow-pitch, and high-pin-count connecting structures with very low mounting heights of less than 0.25 mm. Some examples will now be described in detail.

### EXAMPLES

### Example 1

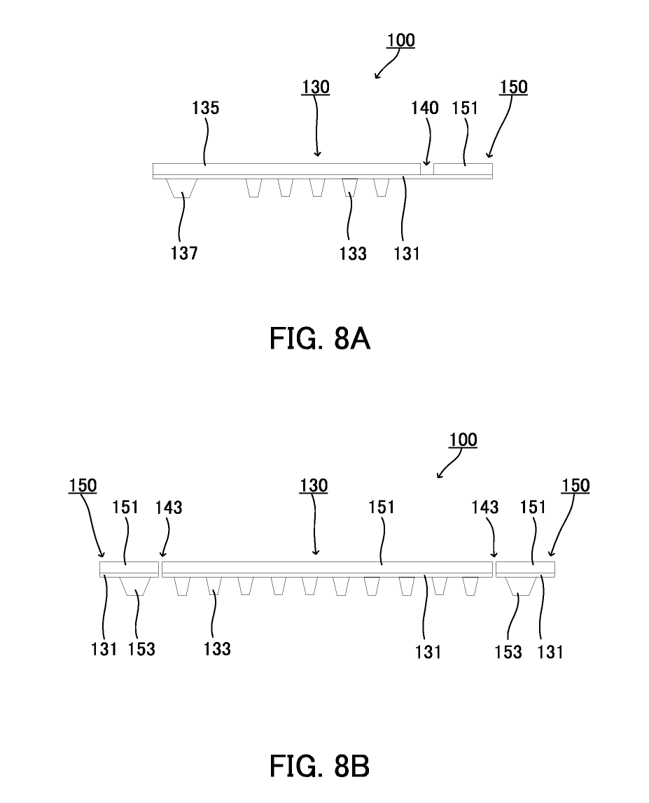

In the present example, a connector illustrated in FIG. 7, FIG. 8A, and FIG. 8B was made. FIG. 7 is a plan view of the connector, FIG. 8A is a cross-sectional view taken along line A-A′ of FIG. 7, and FIG. 8B is a cross-sectional view taken along line B-B′ of FIG. 7.

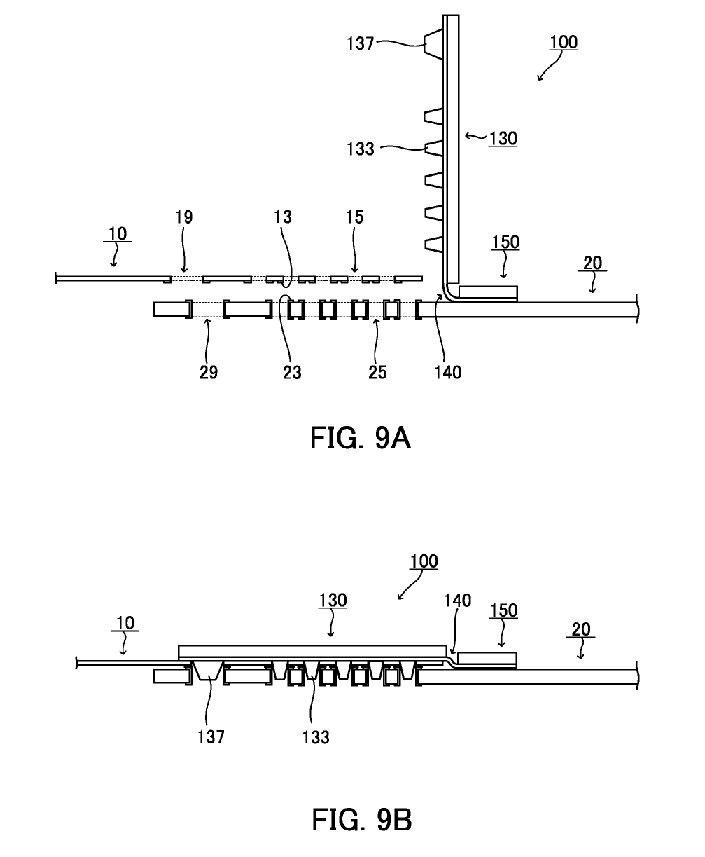

A connector 100 includes a securing member 150 adjacent to a reinforcing member 135 of a connector main body 130. The securing member 150 is configured to secure a third base 131 to one surface of a target member. The securing member 150 and the reinforcing member 135 of the connector main body 130 are disposed such that one end face of the securing member 150 and one end face of the reinforcing member 135 are adjacent to each other at a predetermined distance. The securing member 150 and the reinforcing member 135 form a hinge mechanism 140 which allows the connector main body 130 to pivot about a portion of the third base 131 that bridges the gap between the securing member 150 and the reinforcing member 135 (see FIG. 9A and FIG. 9B). Along other faces where the securing member 150 and the reinforcing member 135 are adjacent to each other, there are slits 143 that extend across the third base 131.

In the connector main body 130, 50 first protrusions 133 are arranged in an array of 10 by 5 with a pitch of 0.8 mm on one surface (backside) of the third base 131.

The reinforcing member 135 of substantially T-shape has a pair of second protrusions 137 for positioning. The second protrusions 137 are located at one side of the reinforcing member 135 distant from the hinge mechanism 140. As illustrated in FIG. 9A, the flexible circuit 10 further has a third through hole 19 for positioning, at a distance from the first conductor circuits (not shown) and the first contact pads 13. Also as illustrated, the target member 20 has a fourth hole 29 for positioning, at a distance from the second conductor circuits (not shown) and the second contact pads 23. The second protrusions 137 for positioning are located at positions corresponding to the third through holes 19 and the fourth holes 29. The diameter (size) of a lower base of each of the second protrusions 137 (truncated cones) is designed such that the second protrusion 137 is passed through the corresponding third through hole 19 and engaged in the corresponding fourth hole 29 for positioning.

The securing member 150 of substantially U-shape has four third protrusions 153 on one surface of the third base 131. The third protrusions 153 are engaged in respective fifth holes (not shown) of the target member 20. The securing member 150 is thus connected to the fifth holes (not shown) of the target member 20 and secures the third base 131 in position.

The connector 100 was made in the following manner.

A 0.050-mm-thick polyimide film was used as the third base 131. The film was directly thermally laminated with a 0.200-mm-thick stainless steel sheet on one side, and with a 0.100-mm-thick stainless steel sheet on the other side. By photolithography and etching, the former stainless steel sheet was processed to integrally form an array of the first protrusions 133, the second protrusions 137 for positioning, and the third protrusions 153 for securing, whereas the latter stainless steel sheet was processed to integrally form the reinforcing member 135 of the connector main body 130 and the securing member 150. Then, the outer shape was mechanically cut out to obtain a material to be processed into the connecter. With the base film for the third base 131 partially left in a linear shape, a slit portion was formed by etching the latter stainless steel sheet. Thus, the hinge function 140 composed of the substantially T-shaped connector main body 130, the substantially U-shaped securing member 150, and the third base 131 for bridging the gap therebetween was produced. The hinge function 140 has a slit width of 0.2 mm and allows pivoting of ±90°.

The first protrusions 133 formed by etching were in the distinct shape of Mount Fuji (inverted mortar) in cross section. It was confirmed that it was possible to change the size of the end portion (upper base) and the size of the foot portion (lower base) by varying the etching conditions.

Next, as a flexible circuit 10, a material layer with a base thickness of 0.025 mm and a copper foil thickness of 0.018 mm was prepared, the material layer being etched with single-sided circuits and double-sided through hole circuits. As another flexible circuit 10, a single-sided flexible circuit was prepared in which a 0.010-mm-thick layer of silver paste was screen-printed on a polyester film with a base thickness of 0.025 mm. As a target member 20, which was a rigid printed circuit board, a double-sided through-hole printed circuit board was obtained by processing a 0.2-mm-thick glass epoxy copper-clad laminate with a typical etching process. The flexible circuit 10 and the target member 20 have the contact pads 13 and 23 with a hole diameter of 0.25 mm. The contact pads 13 and 23 are arranged in an array with the same array dimensions as those of the first protrusions 133 arranged in an array in the connector main body 130.

A securing structure of the present example was assembled in the following manner as illustrated in FIG. 9A and FIG. 9B.

First, the securing member 150 was secured onto a rigid printed circuit board, which was the target member 20, with an isocyanate-based adhesive. The end portion (upper base) of each of the third protrusions 153 of the securing member 150 was 0.015 mm to 0.017 mm in diameter. If the foot portion (lower base) of each of the third protrusions 153 was 0.3 mm or more in diameter, it was possible to manually align the third protrusions 153 with the corresponding fifth holes (not shown) of the target member 20. Next, the hinge mechanism 140 was bent to open the connector main body 130. After the flexible circuit 10 was placed on the target member 20, the connector main body 130 was returned to the original position and secured by applying a pressure thereto. For positioning of the flexible circuit 10, the fourth holes 29 for edge alignment and positional adjustment were used. It was confirmed that both functioned individually.

When a single-sided flexible circuit was used, a height above the front surface of the printed circuit board was less than 0.25 mm after they were joined together. This height is less than a third of that in the thinnest FFC and BTB connectors currently used in mass production. The contact resistance of the connector was less than 50 milliohms per pin.

### Example 2

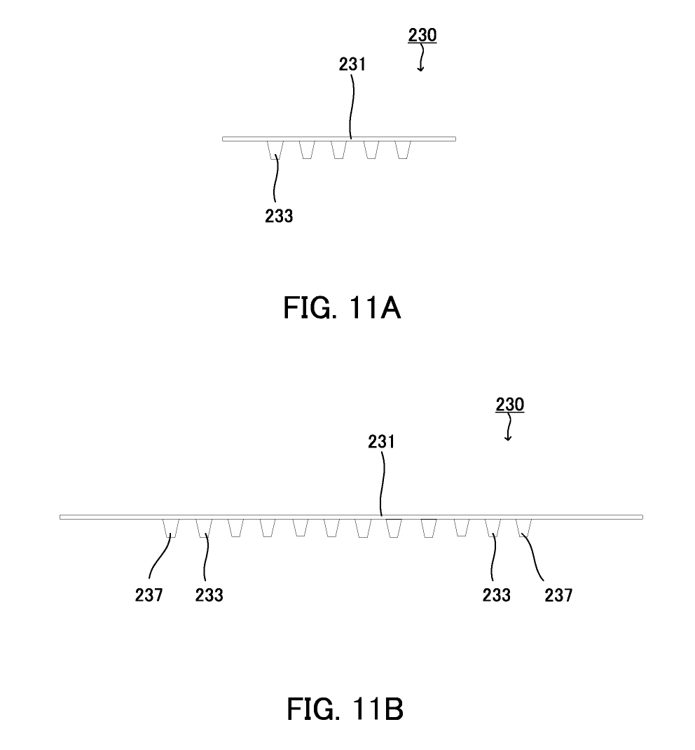

In the present example, a connector illustrated in FIG. 10, FIG. 11A, and FIG. 11B was made. FIG. 10 is a plan view of the connector, FIG. 11A is a cross-sectional view taken along line C-C′ of FIG. 10, and FIG. 11B is a cross-sectional view taken along line D-D′ of FIG. 10.

In a connector 200, a connector main body 230 has a structure in which 50 first protrusions 233 are arranged in an array of 10 by 5 with a pitch of 0.8 mm on one surface (backside) of a strip-shaped third base 231. Second protrusions 237 for positioning are arranged in rows on both sides of the array of the first protrusions 233 (in the up-and-down direction in FIG. 10), each row containing three second protrusions 237. The second protrusions 237 have the same dimensions as those of the first protrusions 233.

The connector 200 was made in the following manner.

A 0.050-mm-thick polyimide film was used as the third base 231. The film was directly thermally laminated with a 0.250-mm-thick stainless steel sheet on one side. The stainless steel sheet was processed by photolithography and etching to integrally form an array of the first protrusions 233 and the second protrusions 237 for positioning. Then, the outer shape was cut out to obtain a connector main body without a reinforcing member.

As in the case of Example 1, the first protrusions 233 formed by etching were in the distinct shape of Mount Fuji (inverted mortar) in cross section. It was confirmed that it was possible to change the size of the end portion (upper base) and the size of the foot portion (lower base) by varying the etching conditions.

Next, as a flexible circuit 40, a material layer with a base thickness of 0.025 mm and a copper foil thickness of 0.018 mm was prepared, the material layer being etched with single-sided circuits. As another flexible circuit 40, a single-sided flexible circuit was prepared in which a 0.010-mm-thick layer of silver paste was screen-printed on a polyester film with a base thickness of 0.025 mm. As a target member 20, which was a rigid printed circuit board, a double-sided through-hole printed circuit board was obtained by processing a 0.2-mm-thick glass epoxy copper-clad laminate with a typical etching process. The flexible circuit 40 has the contact pads 13 provided with the first through holes 16 with a diameter of 0.16 mm to 0.18 mm. The target member 20 has the second contact pads 23 provided with the second holes 25 with a diameter of 0.24 mm to 0.27 mm. The contact pads 13 and 23 are arranged in an array with the same array dimensions as those of the first protrusions 233 arranged in an array in the connector main body 230.

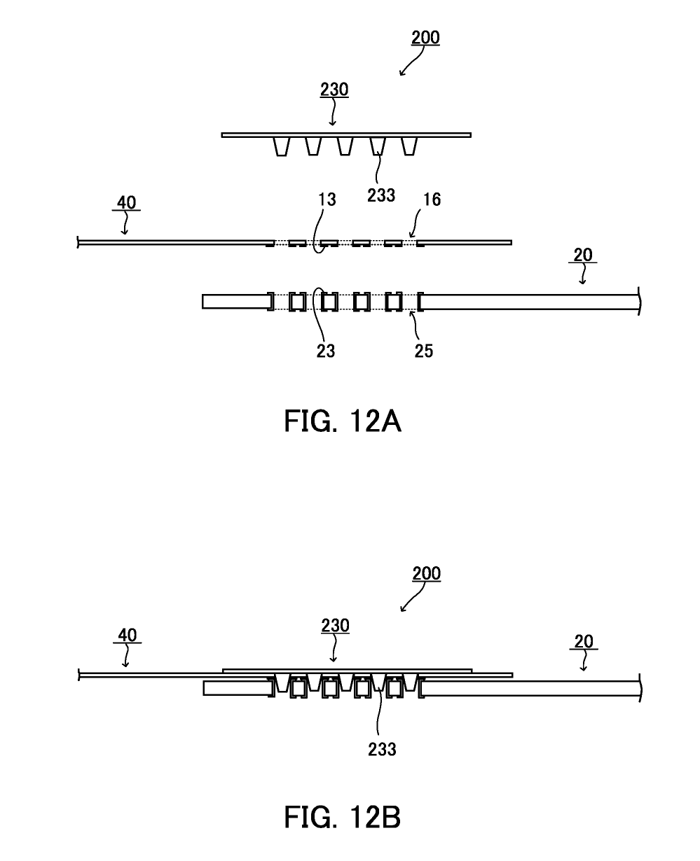

A securing structure of the present example was assembled in the following manner as illustrated in FIG. 12A and FIG. 12B.

First, the flexible circuit 40 was placed on a rigid printed circuit board, which was the target member 20, using a pin guide (not shown). Then, the connector 200 having the first protrusions 233 was joined from above to the flexible circuit 40 using a pressure contacting tool. The end portion (upper base) of each of the first protrusions 233 was 0.20 mm to 0.22 mm in diameter. It was confirmed that the combination of the dimensions of the first through holes 16, the second holes 25, and the first protrusions 233 allowed the joining structure to have a mechanical self-holding capability.

In the joining structure of the present example, a height above the front surface of the printed circuit board was able to be reduced to as low as less than 0.100 mm. This is almost unachievable with the configurations of connectors of related art, and is even lower than the heights of chip components. It was confirmed by a drop impact test that samples made in the present example withstood being dropped from a height of 1 m. The contact resistance of the connector was less than 50 milliohms per pin.

[Modifications]

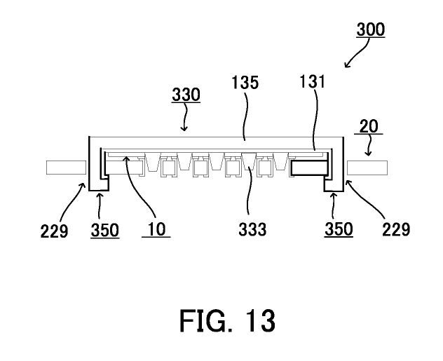

The connecting structure of Example 1 described above can be modified to that illustrated in FIG. 13.

Referring to FIG. 13, a connector 300 includes securing members 350 with hook portions formed by bending a connector main body 330, into an L-shape, at both ends in the transverse direction. When the securing members 350 are passed through the corresponding sixth holes 229 of the target member 20 and locked to the other surface (backside) of the target member 20, first protrusions 333 are passed through the first through holes of the flexible circuit 10 and inserted into the second holes of the target member 20. With this configuration, the sixth holes 229 can be aligned with the securing members 350 with hook portions.

The foregoing embodiments and examples are provided merely for illustrative purposes and various modifications can be made. For example, the first through holes do not have to be circular, but may be of polygonal shape, cross shape, star shape, or other odd shape. The first protrusions do not have to be circular in cross section, but may be odd-shaped in cross section. By appropriately determining the diameter of the circular first contact pads, such odd-shaped first protrusions can be engaged with the inner edges of the first contact pads and partially pressed into the second holes. This can improve reliability of the joining.

Although a plurality of embodiments have been described with reference to the drawings, the present invention is not limited to them. The present invention can be changed without departing from its scope.

### INDUSTRIAL APPLICABILITY

The present invention is suitable for application to a connecting structure for detachably connecting a flexible circuit including a plurality of conductor circuits to a target member, such as a circuit component or a printed circuit board including a plurality of conductor circuits. The present invention is particularly suitable for application to a connecting structure for repeatedly attaching and detaching a thin flexible circuit to and from another printed circuit board or a circuit component.

1. A connecting structure for connecting a flexible circuit to a target member, comprising:
a flexible circuit having first contact pads on at least one surface thereof, the first contact pads being connected to respective first conductor circuits;
a target member having second contact pads on at least one surface thereof, the second contact pads being connected to respective second conductor circuits; and
a connector main body configured to detachably connect the flexible circuit to the target member,
wherein the flexible circuit has first through holes in a plane of the first contact pads, the first through holes passing through the flexible circuit in a thickness direction of the flexible circuit;
the target member has second holes in a plane of the second contact pads, the second holes being formed in a depth direction of the target member and deeper than a thickness of the second contact pads;
the connector main body has first protrusions on one surface of a third base, the first protrusions corresponding to the first through holes of the flexible circuit and the second holes of the target member; and
the connector main body is pressed against the flexible circuit disposed such that the first contact pads face the corresponding second contact pads of the target member, so that the first protrusions of the connector main body are passed through the first through holes of the flexible circuit and inserted into the second holes of the target member, the flexible circuit is mechanically connected to the target member, and an electrical connection between the first contact pads and the second contact pads is established by pressure contacting.

2. The connecting structure according to claim 1, wherein the second holes of the target member are double-sided through holes or blind holes, each having a conductor layer on an inner surface thereof.

3. The connecting structure according to claim 1, wherein the first contact pads are contact pads arranged in an array on the one surface of the flexible circuit, the second contact pads are contact pads arranged in an array on the one surface of the target member, and the first protrusions are protrusions arranged in an array on the one surface of the third base of the connector main body, the first protrusions corresponding to the first through holes of the first contact pads and the second holes of the second contact pads.

4. The connecting structure according to claim 3, wherein the connector main body includes a reinforcing member on the other surface of the third base, the reinforcing member being configured to apply an external force to the first protrusions arranged in an array.

5. The connecting structure according to claim 3, wherein the flexible circuit further has third through holes for positioning, the third through holes being at a distance from the first conductor circuits and the first contact pads;
the target member further has fourth holes for positioning, the fourth holes being at a distance from the second conductor circuits and the second contact pads; and
the connector main body has second protrusions for positioning on the one surface of the third base, the second protrusions corresponding to the third through holes and the fourth holes.

6. The connecting structure according to claim 1, wherein the flexible circuit has the first through holes smaller in size than the second holes of the target member and the first protrusions of the connector main body, the second holes and the first protrusions being substantially the same in size; and
when the first protrusions are passed through the first through holes and inserted into the second holes, the first protrusions press the corresponding inner edges of the first contact pads into the second holes to establish a frictional connection between the flexible circuit and the target member.

7. The connecting structure according to claim 6, wherein the first protrusions have a shape of a truncated cone, and a diameter of an upper base of each of the first protrusions being truncated cones is greater than or equal to a quarter of a height of the truncated cone.

8. The connecting structure according to claim 4, further comprising a securing member adjacent to the reinforcing member of the connector main body, the securing member being configured to secure the third base to the target member.

9. The connecting structure according to claim 8, wherein the securing member and the reinforcing member of the connector main body are disposed such that one end face of the securing member and one end face of the reinforcing member are adjacent to each other at a predetermined distance, and the securing member and the reinforcing member form a hinge mechanism which allows the connector main body to pivot about a portion of the third base that bridges a gap between the securing member and the reinforcing member.

10. The connecting structure according to claim 8, wherein the securing member has third protrusions engaged in the target member.

11. The connecting structure according to claim 2, wherein the first contact pads are contact pads arranged in an array on the one surface of the flexible circuit, the second contact pads are contact pads arranged in an array on the one surface of the target member, and the first protrusions are protrusions arranged in an array on the one surface of the third base of the connector main body, the first protrusions corresponding to the first through holes of the first contact pads and the second holes of the second contact pads.

12. The connecting structure according to claim 2, wherein the flexible circuit has the first through holes smaller in size than the second holes of the target member and the first protrusions of the connector main body, the second holes and the first protrusions being substantially the same in size; and
when the first protrusions are passed through the first through holes and inserted into the second holes, the first protrusions press the corresponding inner edges of the first contact pads into the second holes to establish a frictional connection between the flexible circuit and the target member.

13. The connecting structure according to claim 9, wherein the securing member has third protrusions engaged in the target member.
